(19) United States
(12) Patent Application Publication
(10) Pub. No.: US 2010/0264927 A1
(43) Pub. Date: Oct. 21, 2010

(54) HIGH-PERFORMANCE NANOMATERIAL COIL ARRAYS FOR MAGNETIC RESONANCE IMAGING

(76) Inventor: Raju Viswanathan, St. Louis, MO (US)

Correspondence Address: Russ Weinzimmer, 614 Nashua Street, Suite 53, Milford, NH, 03055, US

(21) Appl. No.: 12/762,330

(22) Filed: Apr. 17, 2010

Related U.S. Application Data
(60) Provisional application No. 61/170,399, filed on Apr. 17, 2009.

(51) Int. Cl. G01R 33/44

(52) U.S. Cl. 324/318

(57) ABSTRACT

Magnetic Resonance Imaging with imaging coils at least partially formed from carbon-based nanomaterials possessing high Signal-to-Noise-Ratio (SNR) are disclosed. The imaging or Radio Frequency receiving coils are constructed with a locally ballistic electrical conductor such as carbon in the form of a macroscopic configuration of carbon nanotubes or variations thereof whose resistance does not increase significantly with length over appropriate local length scales. Due to their enhanced SNR properties, the nanomaterial imaging coils and arrays including the nanomaterial imaging coils can result in significant improvements in imaging with MRI systems. The nanomaterial imaging coils include metal conductors deposited on ends of the coils.

### RELATED APPLICATIONS

This application claims priority to U.S. Provisional Patent Application No. 61/170,399 filed Apr. 17, 2009, which is incorporated herein by reference in its entirety.

### FIELD

This application relates generally to diagnostic medical imaging, and more specifically to magnetic resonance imaging (MRI) at high signal-to-noise ratios (SNR) within the entire anatomy of interest.

### BACKGROUND

MRI technology as a diagnostic imaging modality has led to huge benefits to modern medical science and practice. A significant factor affecting the further increased use of this versatile imaging technology is the image quality that can be obtained with a given MR scanner system in a reasonable time that does not adversely impact patient comfort.

The image quality of MRI is influenced by several factors. An important factor is the SNR associated with the signal acquisition process and in particular with the signal acquisition/imaging coils employed in Radio Frequency (RF) signal reception. Higher levels of SNR may usually be traded off for increased image resolution and/or reduced scan time. Currently imaging coils are constructed from a highly conductive metal, usually copper, and each type of coil is designed for reasonably optimal performance in its respective clinical application. The trend over the last several years has been to increasingly move towards arrays of individual coil elements, as there is generally an inverse relation between the SNR and coil dimensions. Typically, however, this increased SNR comes at the price of decreased depth of penetration, so that several or many array elements may be needed to cover the entire volume of interest with a reasonably high SNR.

Furthermore, the SNR of a coil is limited by the electrical resistance associated with the coil, and more specifically by the effective resistance to induced current flow in both the coil and the tissue of interest (respectively referred to often as coil resistance and body resistance). The SNR is also limited by how much signal energy is contained relative to noise within the bandwidth of interest around the center frequency associated with the scanner magnet. In the case of arrays of coil elements, inductive coupling between the coil elements can act to further reduce SNR and the design of the array needs to take into consideration such mutual interactions.

### SUMMARY

MRI that uses imaging coil elements with high intrinsic SNR are disclosed that can offer advantages in the design of highly effective coil arrays that also can yield high SNR. Methods of coil design and construction are disclosed that take advantage of the electrical properties of low resistance and high gain imaging coils or coil elements formed from carbon-based nanomaterials that are electrical conductors whose resistance does not increase significantly with length of the conductor over length scales of tens of microns or more (also known as ballistic conductors).

These coil elements and their electrical properties can be used to construct imaging arrays that can image the entire volume of interest with significantly higher SNR performance than would be possible with standard conductors. Implementations of embodiments of the present invention are possible over a wide range of field strengths, from 0.2 T or below to 7T or above, and can offer in each case high quality imaging with significantly superior overall performance and image quality.

Imaging coil elements can include at least one electrical conductor formed from carbon-based nanomaterial, with a metal electrode deposited on the electrical conductor. The electrical conductor can be at least one-half of a full turn. The metal electrode can be electrically coupled to tuning components for tuning the imaging coil element. The metal electrode can be deposited by vapor deposition with mechanical pressure. The metal electrode can be formed from at least one of palladium, platinum, silver, gold, and copper.

In some embodiments, one or more capacitors may be positioned along the at least one electrical conductor. Also, in certain embodiments, the second metal electrical conductor can be electrically coupled to the nanomaterial electrical conductor. In some embodiments, the electrical conductor can be a plurality of conductors, and each of the plurality of conductors being formed from carbon-based nanomaterial. Similarly, the imaging coil can be one of a plurality of imaging coils in an imaging coil array.

### BRIEF DESCRIPTION OF THE DRAWINGS

The following description can be better understood in light of the following Figures, in which:

FIG. 1 is a schematic illustration of a nanomaterial imaging coil for use in an MRI machine;

FIG. 2 is a schematic illustration of an array coil in the form of a set of overlapped coil elements showing overlap length and overall array dimensions.

FIG. 3 is an illustration of two coupled coils depicted in the form of coupled resonant circuits;

FIG. 4 is an illustration of the split in the resonant frequencies of the coil elements of FIG. 3; and

FIG. 5 is an illustration of the effective bandwidth of an array coil with a coupled pair of coil elements similar to the coupled coil pair of FIG. 3, due to frequency splitting.

Together with the following description, the Figures demonstrate and explain the principles of nanomaterial imaging coil arrays. In the Figures, the size, number and configuration of components may be exaggerated for clarity. The same reference numerals in different Figures represent the same component.

### DETAILED DESCRIPTION

The following description supplies specific details in order to provide a thorough understanding. Nevertheless, the skilled artisan would understand that embodiments of nanomaterial imaging coils and arrays for MRI machines can be implemented and used without employing these specific details. Indeed, exemplary embodiments and associated methods can be placed into practice by modifying the illustrated units and associated methods and can be used in conjunction with any other devices and techniques conventionally used in the industry.

Embodiments of nanomaterial imaging arrays can include at least one Radio Frequency (RF) transmission coil and at least two RF receiving coil elements each including an electrical conductor formed from carbon nanomaterial in the form of bundles of carbon nanotubes (either single-walled or multi-walled nanotubes or a combination thereof) in the form of sheets, ribbons, wires, ropes, yarns or other configurations, sheets or stacks of graphene, or similar material exhibiting ballistic charge transport characteristics over length scales of about 10 microns or more. Other examples of materials that could potentially have broadly similar characteristics include buckypaper and carbon nanotube-infused polymers, such as carbon nanotubes interspersed or dispersed in a polymeric film with a suitable degree of connectivity. In the following, the term carbon nanomaterial or carbon-based nanomaterial is understood to be, without limitation, any of the above varieties of nano-structured carbon-based materials or other similar forms with generally similar charge transport characteristics.

Carbon nanotubes have many interesting electrical, mechanical and thermal properties. Specifically, at appropriate length scales they possess the property of ballistic electron transport, wherein the electrons transported by the conductor do not get significantly scattered over a certain relaxation time interval, such that the electrical resistance offered by the conductor to a current is independent of length over this length scale. In contrast, the resistance of a standard (metallic) electrical conductor increases linearly with length, other things being equal. Furthermore, ballistic conductors do not exhibit a skin effect such that resistance increases with frequency; in fact, in some cases in the MHz frequency range characteristic of MR Imaging, carbon nanotubes demonstrate a weak decreasing dependence of resistance on frequency (for instance, this is discussed in Y.P. Zhao et al, Physical Review B, Volume 64, 2001, p. 201402(R)).

Recently, processes have been developed to fabricate useful lengths of carbon nanotube conductors in the form of thin sheets (M. Zhang et al, Science, Aug. 19, 2005, p. 1215), wires or twisted yarns. Individual thin sheets can be as thin as 50 nanometers; in other forms the effective thickness of the carbon nanomaterial conductor can be no more than a few millimeters while retaining excellent electrical transport properties such as low resistance and high inductance that are advantageous for imaging coils. At radio frequencies of interest to magnetic resonance imaging, a receiving coil comprising such material can have a relatively low intrinsic resistance due to the material's locally ballistic conductance properties and the absence of the skin effect common to metallic (scattering) conductors. In addition the coil can display enhanced inductance properties due to the intrinsic or kinetic inductance associated with a relatively long charge transport relaxation time scale. This combination of properties can yield significant increases in SNR performance even in the presence of body noise or noise arising from resistance to the flow of induced eddy currents in the subject body.

The carbon nanotube conductors can be either Single-Walled Nanotubes or Multi-Walled Nanotubes, methods of construction of both of which are known and described in the literature. While Multi-Walled Nanotubes are employed in the sheet drawing method described in M. Zhang et al, Science, Aug. 19, 2005, p. 1215, for example K. Hata et al, Science, Vol. 306, 19 Nov. 2004, p. 1362, describes a technique for the water-assisted synthesis of Single-Walled Carbon Nanotubes. This technique can provide patterned, highly organized nanotube structures including sheets and pillars and nanotube forests, from which further macroscopic structures such as sheets or films could be fabricated by means of a drawing process. The growth of the initial nanotube structures or forests can often benefit from the presence of catalysts such as Iron nanoparticles together with a suitable substrate such as Silicon. In some cases a suitable doping agent such as Hydrogen can yield further decreases in resistance of sheets drawn from the nanotube forests. The advantages of doping of both Single-Walled Nanotubes and Multi-Walled Nanotubes are described for instance in M. Zhang et al, Science, Aug. 19, 2005, p. 1215. The examples of film or sheet construction methods in the above are discussed for illustrative purposes only. Those skilled in the art can conceive or design alternate fabrication or construction methods without departing from the scope of the present invention.

Electron transport in a material can be phenomenologically described by the Drude model, which models the motion of an electron under the influence of an electric field E caused by a potential gradient in terms of the Drude equation:

m(\ddot{x}+γ\dot{x}+ω₀²x)=−eE (1)

where m is the mass of the electron, (−e) its charge, γ is a damping constant and the last term on the left is a restoring force on a bound electron. Together with Maxwell's equations and Ohm's law (constitutive equation) for the current density in the form J=σE, it can be shown that the above equation can be used to write the resistivity ρ for the material at frequency ω in the form

$$ρ = \frac{m}{n {e}^{2} τ} ( 1 + iωτ ) \qquad ( 2 )$$

where τ is the relaxation time and n is the volumetric number density of electrons.

Relaxation time may also be interpreted as the mean time between momentum transfer or scattering events. From equation (2), it is evident that the resistivity has an imaginary part that linearly increases with frequency ω; this can therefore be physically interpreted as an inductance. It is referred to as kinetic inductance since it arises from the inertia of the charge carriers, in contrast to the usual inductance that arises purely from the geometry of the current distribution. In the case when transport is locally ballistic, as can be the case with carbon-based nanomaterials, the relaxation time τ can be relatively long, leading to significant contributions to the overall inductance from the kinetic part. At the same time, with sufficiently high density of cross-sectional packing of nanotube bundles, the carbon-based nanomaterial can be made to have low resistance at radio frequencies. As mentioned earlier, this combination of properties can yield significant increases in SNR performance of an imaging coil constructed as disclosed herein.

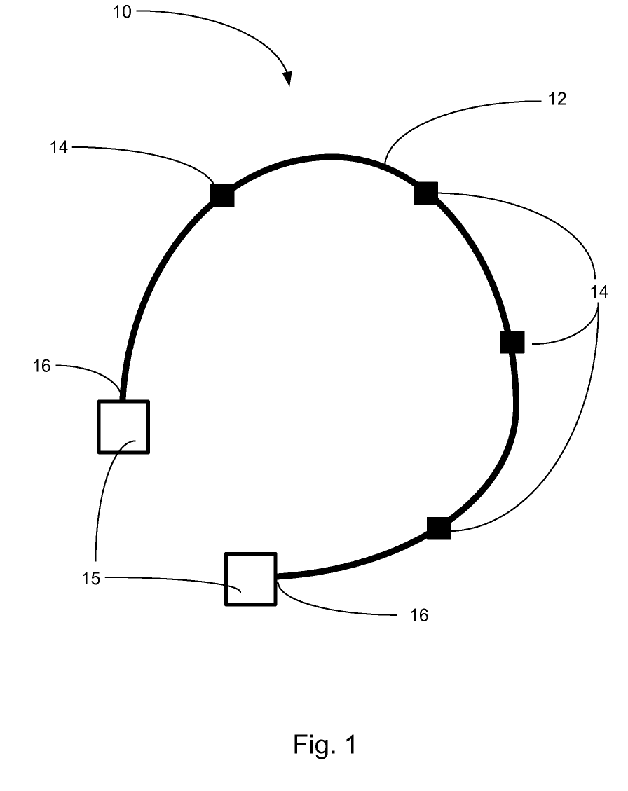

Turning now to FIG. 1, embodiments of nanomaterial imaging coil 10 can include at least about half a turn of conducting element 12. For example, conducting element 12 can be a hybrid construction that includes both carbon nanomaterial and metal. Conducting element 12 can include capacitors 14 located at one or more locations in breaks along its length to distribute capacitance and minimizing the electric fields that may arise near conducting element 12 due to local charge accumulations during RF current flow or charge transport.

In some embodiments, conducting element 12 is itself further connected at its ends 16 to electronic circuitry (not shown) including tuning elements such as capacitors and inductors. For example, one can attach metallic conductors 16 to the free ends of conductor 12 in the form of metal electrodes 15 attached by deposition of palladium, platinum, silver, or any other suitable metal or metal alloy. Other electrically conductive materials besides the ones mentioned above, including gold and copper, can be used in the formation of the carbon-nanotube metal junction. The examples of metals and attachment processes given here is for purposes of non-limiting example only and other metals with similar properties and other attachment methods could be used as convenient without departing from the spirit and scope of the present invention.

The deposition of metallic conductors 16 can be done by direct application of a molten metal paste to form a carbon nanotube-metal junction between ends 15 and metallic conductors 16, vapor deposition with application of mechanical pressure, using a sputtering process, or any other metal application and deposition methods and techniques. For example, standard microlithographic techniques or masked deposition may be used.

In some cases, the role of a substrate could be played by another nanotube sheet or film, arranged in a layered construction or sheet stacking, all attached to a single underlying thin substrate such as a polymer film. The attachment in one embodiment could be either by direct adhesion or due to surface tension effects, while in an alternate embodiment surface tension effects could be augmented by attaching the carbon nanotube sheet(s) to the substrate at the ends by metal electrodes.

The tuning circuitry mentioned above can be used to tune the coil to preferentially receive RF electrical signals in a relatively narrow bandwidth around the center frequency associated with the scanner magnet, and to match the effective coil impedance to a specified/desired preamplifier impedance for optimal signal transfer to the scanner. The tuning may be accomplished by any known tuning method. The sharpness of the tuning is measured by the Quality Factor Q, defined for the bare coil to be the ratio (ωL/R) of the inductive reactance to the resistance associated with the coil (generally while in interaction with the subject tissue). A sharper tuning or higher Q factor leads to relatively more signal energy captured by the coil compared to the noise picked up by the coil at the same time. Considering a nanomaterial coil according to the present invention with a Quality Factor value Qₙ, one can define a corresponding Quality Factor Qₛ for a standard coil with a completely metallic conducting element (for example made of copper) of closely identical form factor or overall dimensions to the nanomaterial coil. By using a sufficient quantity of nanomaterial so as to provide an appropriate cross section for charge transport, the nanomaterial coil of the present invention can be built so as to possess a ratio Qₙ/Qₛ that can be at least 1.05, extending to at least 1.1, and even at least 1.2. The ratio reflects quality gains that can be more than 20%.

In order to prevent signal pickup by the coil during system transmit mode, PIN diodes may be included in the circuitry at various locations, either as part of a board for the tuning circuitry for the coil, or at the breaks in the conducting element. In some cases the PIN diodes can be actively turned on by application of a suitable bias voltage that can then activate circuitry that serves to block signals in the coil.

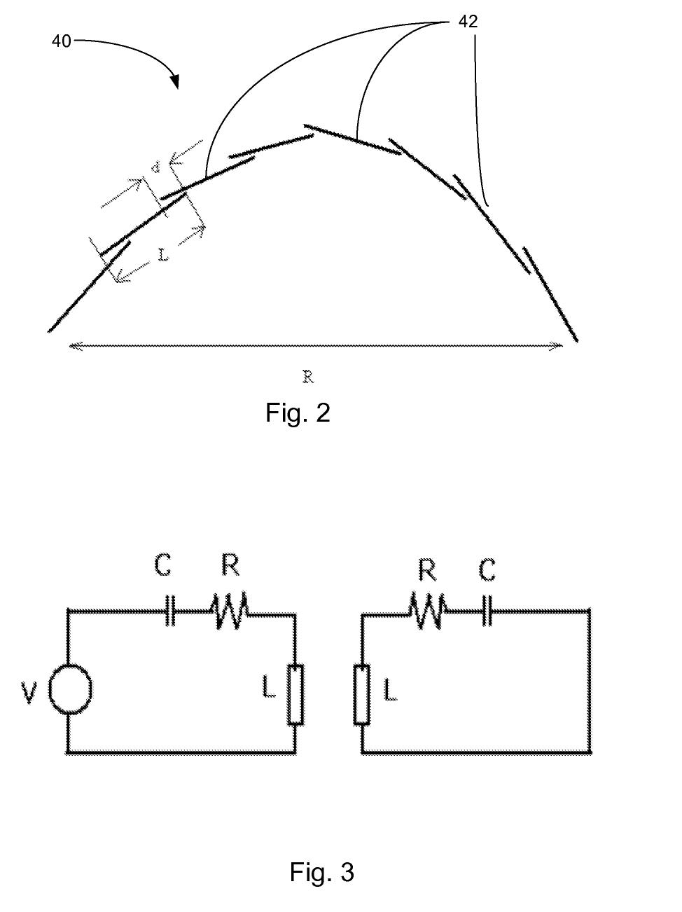

Furthermore, RF imaging array coil 40, as shown in FIG. 2, can be constructed as a composite of individual nanomaterial imaging coil elements 42, constructed similar to nanomaterial imaging coil 10 above. In such embodiments, the bandwidth associated with array coil 40 can be smaller than that of a conventional coil. Such a relative reduction in bandwidth for array coil 40 can be at least five percent, more preferably 10 percent and still more preferably at least 20 percent as compared to a conventional coil. With N coil elements 42, when the elements are configured in array coil 40 so that the signals received from at least a portion of the volume are additive, in the best case that the noise from the individual elements are uncorrelated, the total noise has a standard deviation of \sqrt{N}, while the total signal is N times the signal from an individual element. Thus the SNR of the array can display an ideal or theoretical increase of a factor of \sqrt{N}.

In this case the spatial placement of individual coil elements 42 can be chosen to optimize SNR within a desired region of interest so as to approach the theoretical maximum as much as is practical. One measure that is usually desirable to maximize is the signal received from everywhere within the region of interest in the tissue. It is also desirable to minimize the mutual coupling between coil elements in the array, as determined for instance by the mutual inductance of a given pair of coil elements. Besides increasing effective resistance and thence decreasing signal from the coil, such an interaction or coupling can cause correlations in the noise and thus increase the total noise standard deviation, thereby adversely affecting the array SNR. Nanomaterial imaging coil elements 42, 10 and the array constructions as taught herein can offer some advantages in this regard.

Consider the two resonant circuits depicted in FIG. 3. In this figure, each of the inductors in the two circuits has an inductance L while the capacitors have a capacitance C. Likewise we assume equal resistances R. The two inductors are coupled by a cross or mutual inductance M (not shown in the figure). When a sinusoidal voltage source of amplitude V is introduced in circuit 1 on the left, the circuit equations for the respective circuits 1 and 2 can be written in the form:

$${I}_{1} R + j ( ω L - \frac{1}{ω C} ) {I}_{1} + j ω M {I}_{2} = V$$

$${I}_{2} R + j ( ω L - \frac{1}{ω C} ) {I}_{2} + j ω M {I}_{1} = 0$$

I₁ and I₂ are the respective currents.

If only circuit 1 is present, it is well known that it has a resonance frequency of ω₀=1/\sqrt{LC}. When both circuits are present with a mutual inductance present as in FIG. 1, it can be shown from the above equations that the resonance frequency splits into two frequencies, given by

$${ω}_{1}^{2} = \frac{1}{LC ( 1 + \frac{M}{L} )}$$

$$and$$

$${ω}_{2}^{2} = \frac{1}{LC ( 1 - \frac{M}{L} )}$$

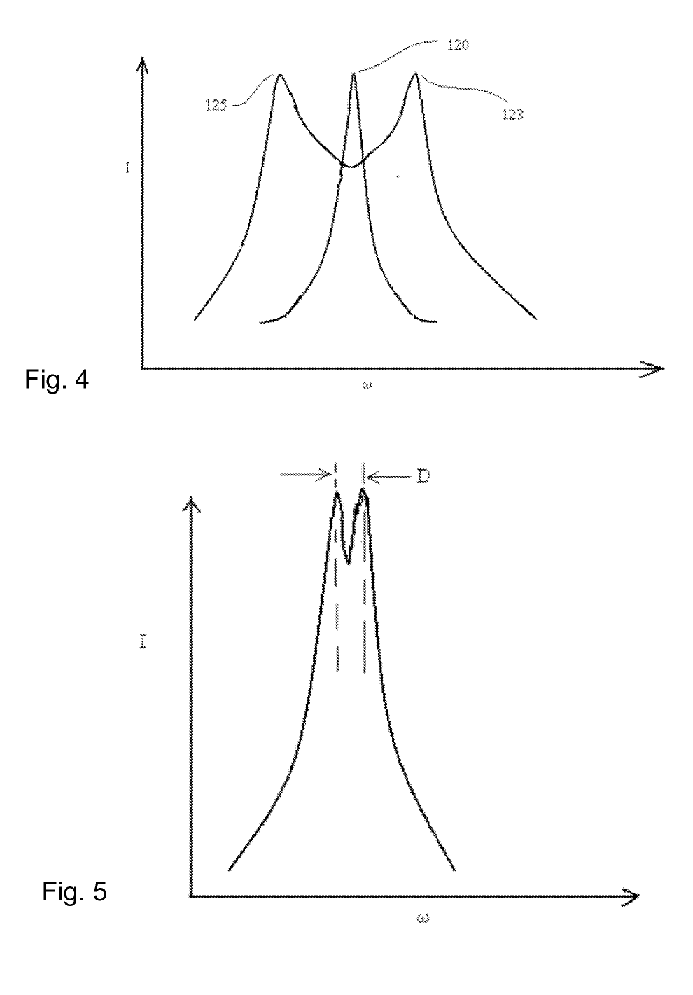

The presence of the mutual inductance or non-zero coupling between the circuits induces a split in the resonance frequency. This is shown in FIG. 4 which shows a schematic plot of current vs. frequency for either circuit. In this Figure, the original resonance frequency 120 in the case of a single circuit splits into two frequencies 123 and 125 when there are two circuits coupled by a mutual inductance. In particular, this split depends on the ratio β=(M/L). For small values of this ratio, the split or difference between the resonant frequencies can be expanded as:

$$( {ω}_{2} - {ω}_{1} ) \approx \frac{1}{2} \frac{1}{\sqrt{LC}} \frac{M}{L} = \frac{1}{2} {ω}_{0} β$$

Larger values of the mutual inductance M relative to the circuit self-inductance L lead to larger frequency splits. Conversely, larger values of the circuit self-inductance L relative to the mutual inductance M lead to smaller frequency splits. For an array of nanomaterial imaging coil(s) where at least some of the coils are formed from carbon nanomaterial, due to the inductance properties mentioned earlier, the ratio β can be relatively small compared to an array coil constructed with metallic conductors or nanomaterial imaging coil elements only.

Now consider an array coil with two (loosely-coupled) coil elements with a non-zero mutual inductance. FIG. 5 shows that when there is a split in resonant frequency due to mutual coupling, the bandwidth of the array can be approximated by the total split in frequency, D. Clearly the bandwidth is larger than it would be for the case of a single coil. Although the intent with such a coil is to reduce the mutual coupling to zero, in practice there can often be a small residual coupling and a consequent increase in bandwidth. Thus, in some embodiments, an array of nanomaterial imaging coils can yield that since β can be smaller in this case, the effective array bandwidth can be smaller or tighter than would be the case for a conventional coil constructed without the benefit of nanomaterial imaging coils.

Coil array 40 with multiple nanomaterial imaging coil elements 42 of identical dimensions is schematically illustrated in FIG. 2, where the overlap d between adjacent nanomaterial imaging coil elements 42 and size L of each nanomaterial imaging coil element 42 in array 40 is shown, as well as an overall array dimension R. In this schematic figure each coil element is visualized edge-on. The choice of overlap dimension d can depend on the specific inductance and resistance properties of the coil elements. Likewise the optimal separation of non-nearest-neighbor coil elements can depend on the specific inductance and resistance properties of the coil elements. Given the relatively small value of the parameter β for the coils of the present invention, the overall size of an array coil of given coil element dimensions can be somewhat smaller than that of a conventional coil with similar-sized coil elements. One consequent advantage is that the individual nanomaterial imaging coil elements can be closer to the subject volume being imaged, thereby providing a further augmentation in SNR.

The nanomaterial imaging coils taught herein can be used for either radio frequency reception or signal transmission or both. The larger quality factor or smaller effective bandwidth of the nanomaterial imaging coils also has positive consequences for signal transmission. By the principle of electromagnetic reciprocity, the nanomaterial imaging coils can also transmit with smaller bandwidth. This means that in transmit mode, a higher proportion of the transmitted RF energy is present within the bandwidth region of frequencies, and a smaller proportion is wasted outside. For instance a desired magnetic field amplitude can be produced by a transmit nanomaterial imaging coil with a smaller applied transmit voltage. Thus, the transmit power requirements for the nanomaterial imaging coils can be smaller than for conventional coils of similar dimension constructed without the benefit of the present invention.

In magnetic resonance imaging, the Specific Absorption Rate (SAR) is a measure of the portion of transmitted power that is deposited per unit mass of tissue during transmission of a radio frequency pulse. Considerations around SAR are a significant issue in MRI radio frequency pulse transmission since power deposition/absorption in tissue can cause heating, even in local regions. If a transmitted pulse is relatively broadband in nature, power from across the frequency width of the coil-generated transmission spectrum is deposited in tissue. On the other hand, for a relatively narrow transmit bandwidth with the same peak amplitude, less power is deposited in tissue from outside the bandwidth region. Thus, since relatively lower power is deposited in or absorbed by the tissue due to the relatively narrow transmit bandwidth of the nanomaterial imaging coils, an advantage of the nanomaterial imaging coils described herein is that they are safer for use in patients compared to conventional coils constructed. A transmit nanomaterial imaging coil can reduce the effective SAR by at least five, ten or twenty percent.

The spatial variation in the signal reception or coil sensitivity profile associated with an array of nanomaterial coils can be determined, for example from computational simulation and possibly comparison with direct measurements. This information can be used with an array of nanomaterial coils constructed as described above in some parallel imaging signal acquisition methods, for example in the SENSE encoding scheme familiar from the MRI literature, to boost the speed and quality of image acquisition. Alternatively or in addition, in some cases the spatial sensitivity profile can be used to normalize the image to produce a smoother, more uniform image signal within a desired field of view.

Another application for an array with nanomaterial imaging coils is MR spectroscopy, where it is desired to image or detect the presence of atomic nuclei other than the standard Hydrogen. Examples of such other nuclei of interest include Sodium-23, Fluorine-19 or Carbon-13 and they generally have different resonant frequencies at a given imaging magnet field strength. Often, the intrinsic signal associated with these nuclei can be small due to their relatively smaller abundance in the subject anatomy, and the higher SNR numbers possible with the coils of the present invention can be valuable in such applications. In one embodiment, a nanomaterial imaging element can be selectively tuned for more than one nucleus by electronic means, for example by the use of voltage-controlled varactors which can be used to change the tuning of the coil by the application of an appropriate voltage level. In other embodiments, at least one nanomateria imaging coil element of an array can be tuned to a different frequency corresponding to reception of signal from a different nucleus than the rest of the coil elements in the array. In some applications instead of direct imaging, a detected radio frequency signal strength may suffice to indicate the presence or relative concentration of a desired atomic nucleus. In this manner various atomic nuclei can be selectively detected or imaged.

A related application is chemical shift imaging, where the resonance frequency of an atomic nucleus of interest can be shifted by a small amount due to interactions with the local molecular environment. For example a metabolite such as choline can have a slight shift in its Hydrogen signal and a spectral analysis of the peaks in the detected radio frequency signal can reveal the presence or absence and/or relative proportions of appropriate molecules within a small region of interest in the anatomy. Detection of such signals may in some cases benefit from a broader band signal reception, which can be achieved with an array coil of the present invention by employing coil elements that are tuned with small relative offsets in tuning frequency. The imaging benefits derived from the nanomaterial imaging coils can be obtained over a wide range of magnet system field strengths, from 0.2T or smaller to 7T or higher.

In addition to any previously indicated modification, numerous other variations and alternative arrangements can be devised by those skilled in the art without departing from the spirit and scope of this description, and appended claims are intended to cover such modifications and arrangements. Thus, while the information has been described above with particularity and detail in connection with what is presently deemed to be the most practical and preferred aspects, it will be apparent to those of ordinary skill in the art that numerous modifications, including, but not limited to, form, function, manner of operation and use can be made without departing from the principles and concepts set forth herein. Also, as used herein, examples are meant to be illustrative only and should not be construed to be limiting in any manner.

1. A tuned imaging coil element for magnetic resonance imaging, the tuned imaging coil element comprising:
at least one electrical conductor formed from carbon-based nanomaterial, the at least one electrical conductor being formed such that the tuned imaging coil element has a higher inductance, a lower resistance, and a quality factor at least 20% larger than a metallic conducting element having the same dimensions as the at least one electrical conductor; and
a metallic conductor deposited on an end of the at least one electrical conductor and configured to conduct an electrical signal between an MRI machine and the tuned imaging coil element.

2. The tuned imaging coil element of claim 1, wherein the tuned imaging coil element is configured to be used for at least one of transmission and reception of radio frequency signals, and wherein the tuned imaging coil element is configured to operate in magnetic fields having strengths between about 0.2 T to about 7 T.

3. The tuned imaging coil element of claim 1, wherein a transmit power requirement for the tuned imaging coil element at a given radio frequency pulse sequence is at least ten percent smaller than a transmit power requirement for the same radio frequency pulse sequence for a similarly dimensioned and similarly tuned metallic imaging coil element.

4. The tuned imaging coil element of claim 1, wherein a Specific Absorption Rate of the tuned imaging coil element is at least ten percent smaller than a Specific Absorption Rate in the same tissue type and for the same radio frequency pulse sequence for a similarly dimensioned and similarly tuned metallic imaging coil element.

5. The tuned imaging coil of claim 1, wherein the at least one electrical conductor is one of a plurality of electrical conductors in an array coil.

6. The tuned imaging coil of claim 5, wherein a transmit power requirement for the array coil is at least ten percent smaller than the transmit power requirement for the same radio frequency pulse sequence for a similarly dimensioned and similarly tuned metallic array coil.

7. The tuned imaging coil of claim 5, wherein a Specific Absorption Rate of the array coil is at least ten percent smaller than a Specific Absorption Rate in the same tissue type and for the same radio frequency pulse sequence for a similarly dimensioned and similarly tuned metallic array coil.

8. An array imaging coil for magnetic resonance imaging, the array imaging coil comprising:
a plurality of tuned coil elements, each tuned coil element acting as an independent imaging channel, wherein at least one of the plurality of tuned coil elements includes at least one nanomaterial conducting element, the at least one of the plurality of tuned coil elements being formed such that,
inductance is higher than a similarly dimensioned metallic coil element,
resistance is lower than a similarly dimensioned metallic coil element, and
bandwidth is smaller by at least 20% than the bandwidth of a similarly dimensioned and similarly tuned metallic coil element.

9. The array imaging coil of claim 8, wherein two adjacent coil elements of the plurality of tuned coil elements are positioned to partially geometrically overlap each other, and wherein the amount of overlap is based on the inductance and resistance properties of each of the two adjacent coil elements.

10. The array imaging coil of claim 8, where two adjacent coil elements of the plurality of tuned coil elements have a relative separation determined by the inductance and resistance properties of each of the two adjacent coil elements.

11. The array imaging coil of claim 8, wherein each of the plurality of tuned coil elements includes at least one nanomaterial conducting element.

12. The array imaging coil of claim 8, wherein each of the plurality of tuned coil elements is geometrically positioned relative to each other tuned coil element of the plurality of tuned coil elements so as to optimize performance of the array imaging coil.

13. An imaging coil element for magnetic resonance imaging, the imaging coil element comprising:
at least one electrical conductor formed from carbon-based nanomaterial, the at least one electrical conductor having a first end and a second end;
a first metal electrode deposited on the first end; and
a second metal electrode deposited on the second end, at least one of the first and second metal electrodes being configured to be coupled to tuning components for tuning the imaging coil element.

14. The imaging coil element of claim 13, wherein the first and second metal electrodes are deposited by vapor deposition with mechanical pressure.

15. The imaging coil of claim 13, wherein the first and second metal electrodes are affixed to the at least one electrical conductor.

16. The imaging coil of claim 13, wherein the first and second metal electrodes are formed from at least one of palladium, platinum, silver, gold, and copper.

17. The imaging coil of claim 13, further comprising at least one capacitor positioned along the at least one electrical conductor.

18. The imaging coil of claim 13, further comprising at least a second electrical conductor coupled to the at least one electrical conductor, the second electrical conductor being formed from metal.

19. The imaging coil of claim 13, wherein the at least one electrical conductor is at least one-half of a full turn.

20. The imaging coil of claim 13, wherein the at least one conductor is a plurality of conductors, and wherein each of the plurality of conductors is formed from carbon-based nanomaterial.

21. The imaging coil of claim 13, wherein the imaging coil is one of a plurality of imaging coils in an imaging coil array.
